(19) United States
(12) Patent Application Publication
(10) Pub. No.: US 2018/0174658 A1
(43) Pub. Date: Jun. 21, 2018

(54) MACHINE LEARNING APPARATUS, LIFE PREDICTION APPARATUS, NUMERICAL CONTROL DEVICE, PRODUCTION SYSTEM, AND MACHINE LEARNING METHOD FOR PREDICTING LIFE OF NAND FLASH MEMORY

(71) Applicant: FANUC CORPORATION, Yamanashi (JP)

(72) Inventor: Kazuya KIKUCHI, Yamanashi (JP)

(21) Appl. No.: 15/838,731

(22) Filed: Dec. 12, 2017

(30) Foreign Application Priority Data
Dec. 15, 2016 (JP) 2016-243357

(51) Int. Cl. G11C 16/34; G06F 3/06; G06N 5/04; G06N 3/08; G06F 15/18

(52) U.S. Cl. CPC G11C 16/3495; G06F 3/0679; G05B 19/18; G06N 3/08; G06F 15/18; G06N 5/04

(57) ABSTRACT

A machine learning apparatus which learns the predicted life of a NAND flash memory provided in a numerical control device includes a state observation unit which observes state variables obtained based on at least one of the rewrite count, the rewrite interval, the read count, the temperature in the use environment, the error rate, information concerning the manufacturer, and information concerning the manufacturing lot for the NAND flash memory, and information concerning the ECC (Error Correction Coding) performance, information concerning the manufacturer, and information concerning the manufacturing lot for a memory controller which performs ECC processing for the NAND flash memory, and a learning unit which learns the predicted life of the NAND flash memory based on teacher data, and training data generated from the output of the state observation unit and data associated with the life of the NAND flash memory.

### BACKGROUND OF THE INVENTION

### 1. Field of the Invention

The present invention relates to a machine learning apparatus, a life prediction apparatus, a numerical control device, and a production system for predicting the life of a NAND flash memory.

### 2. Description of the Related Art

An NC (Numerical Control) device for a machine tool includes NAND flash memories to store various data and processing programs. In this specification, the NC device (Numerical Control device) also includes a CNC (Computerized Numerical Control) device.

In the NAND flash memory, as the number of rewrite operations including information erasure and write increases, the rate of occurrence of bit errors in which retained data is inverted also it creases. The bit errors occurred can be corrected to a certain extent by ECC (Error Correction Coding or Error Check and Correct) processing. ECC processing is performed for the NAND flash memory by a controller connected to the NAND flash memory. The controller that performs ECC processing will be referred to as a “memory controller” in the present disclosure for distinctions from a cell controller (to be described later). The correction processing capacity of ECC processing by the memory controller is limited, and the end of the life is finally reached. Not only the rewrite count and the rewrite interval of the NAND flash memory, but also the read count or the temperature in the use environment of the NAND flash memory influences the life. The life also varies in each individual manufacturer or manufacturing lot for the NAND flash memory. The correction capacity of ECC processing also influences the life of the NAND flash memory. The life of the NAND flash memory even varies depending on the combination of a NAND flash memory and a controller which performs ECC processing for the NAND flash memory.

As disclosed in, e.g., Japanese Unexamined Patent Publication (Kokai) No. 2009-003843, a data management apparatus for a flash ROM is known which manages data stored in the flash ROM used as a data retaining device for an on-board electronic device, and includes a time prediction means for predicting the time for which the data stored in the ROM is retainable, based on the device properties and/or the usage conditions of the flash ROM, and a rewrite means for rewriting the data stored in the flash ROM before the time for which the data is retainable elapses.

A technique is also known for explicitly notifying maintenance personnel of replacement of a flash memory, as disclosed in, e.g., Japanese Unexamined Patent Publication (Kokai) No. 2009-230660.

Another technique is known for predicting the error rate of a flash memory and providing the error prediction to an error correction algorithm, as disclosed in, e.g., Japanese Unexamined Patent Publication (Kokai) No. 2014-517970.

### SUMMARY OF INVENTION

The life of a NAND flash memory provided in a numerical control device for a machine tool varies depending on, e.g., the rewrite count, the rewrite interval, the read count, the temperature in the use environment, the manufacturer, the manufacturing lot, and the correction capacity of ECC, and is therefore hard to accurately predict. When the life of a NAND flash memory provided in a numerical control device may not be accurately predicted, an appropriate timing to replace the NAND flash memory may be missed. When, for example, a NAND flash memory which has come to the end of its life (or suffers failure due to the end of its life) continues to be used as-is, a machine tool and a production line including this tool may be stopped, a defect may occur in a product manufactured by the machine tool, or a serious accident may happen. Further, when, for example, the predicted life of a NAND flash memory is shorter (earlier) than its actual life, the NAND flash memory that has not yet come to the end of its life is wastefully prematurely replaced, and this is uneconomical. It is, therefore, desired to accurately grasp the life of a NAND flash memory provided in a numerical control device for a machine tool and appropriately, easily determine whether the end of the life has been reached.

In one aspect of the present disclosure, a machine learning apparatus which learns a predicted life of a NAND flash memory provided in a numerical control device for a machine tool includes a state observation unit which observes a state variable obtained based on at least one of a rewrite count, a rewrite interval, a read count, a temperature in a use environment, an error rate, information concerning a manufacturer, and information concerning a manufacturing lot for the NAND flash memory, and information concerning an ECC (Error Correction Coding) performance, information concerning a manufacturer, and information concerning a manufacturing lot for a memory controller which performs ECC processing for the NAND flash memory, and a learning unit which learns the predicted life of the NAND flash memory based on teacher data, and training data generated from output of the state observation unit and data associated with a life of the NAND flash memory.

In another aspect of the present disclosure, a machine learning method for learning a predicted life of a NAND flash memory provided in a numerical control device for a machine tool includes the steps of observing a state variable obtained based on at least one of a rewrite count, a rewrite interval, a read count, a temperature in a use environment, an error rate, information concerning a manufacturer, and information concerning a manufacturing lot for the NAND flash memory, and information concerning an ECC (Error Correction Coding) performance, information concerning a manufacturer, and information concerning a manufacturing lot for a memory controller which performs ECC processing for the NAND flash memory, and learning the predicted life of the NAND flash memory based on teacher data, and training data generated from the state variable and data associated with a life of the NAND flash memory.

### BRIEF DESCRIPTION OF THE DRAWINGS

The present invention will be understood more clearly by referring to the following accompanying drawings:

FIG. 1 is a block diagram schematically illustrating an exemplary numerical control apparatus which controls a machine tool;

FIG. 2 is a block diagram illustrating a machine learning apparatus according to one embodiment;

FIG. 3 is a flowchart illustrating the operation sequence of a machine learning method according to one embodiment;

FIG. 4 is a block diagram illustrating the machine learning apparatus using supervised learning according to one embodiment;

FIG. 5 is a flowchart illustrating the operation sequence of a machine learning method using supervised learning according to one embodiment;

FIG. 6 is a schematic diagram illustrating a model of a neuron;

FIG. 7 is a schematic diagram illustrating a neural network having the weights of three layers D1 to D3;

FIG. 8 is a diagram for explaining an exemplary learning mode in the machine learning apparatus using supervised learning according to one embodiment;

FIG. 9 is a diagram for explaining an exemplary prediction mode in the machine learning apparatus using supervised learning according to one embodiment;

FIG. 10 is a block diagram illustrating a machine learning apparatus which learns based on training data acquired for NAND flash memories and/or memory controllers;

FIG. 11 is a block diagram illustrating a life prediction apparatus according to one embodiment;

FIG. 12 is a block diagram illustrating the life prediction apparatus connected to a communication network according to one embodiment;

FIG. 13 is a block diagram illustrating a numerical control device including the life prediction apparatus according to one embodiment;

FIG. 14 is a block diagram illustrating a first embodiment of a production system including the life prediction apparatus;

FIG. 15 is a block diagram illustrating a second embodiment of a production system including the life prediction apparatus; and

FIG. 16 is a block diagram illustrating a third embodiment of a production system including the life prediction apparatus.

### DETAILED DESCRIPTION

A machine learning apparatus, a life prediction apparatus, a numerical control device, a production system, and a machine learning method will be described below with reference to the drawings. In the drawings, similar reference numerals denote similar members. The same reference numerals in different drawings denote components having the same functions. To facilitate an understanding, these drawings use different scales as appropriate.

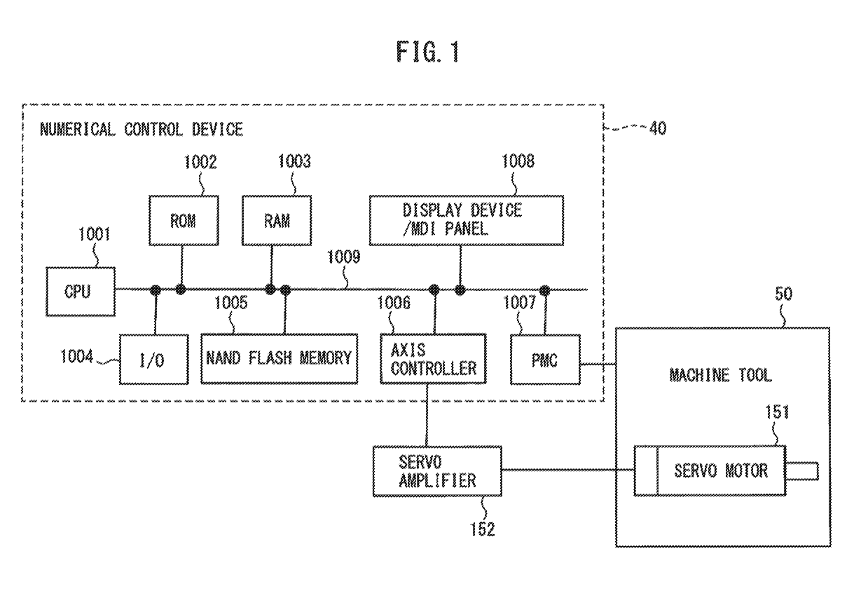

FIG. 1 is a block diagram schematically illustrating an exemplary numerical control device which controls a machine tool.

A numerical control device 40 includes, e.g., a CPU (Central Processing Unit) 1001, a ROM (Read Only Memory) 1002, a RAM (Random Access Memory) 1003, an I/O (Input/Output) 1004, a NAND flash memory 1005, an axis controller 1006, a PMC (Programmable Machine Controller) 1007, and a display device/MDI (Manual Data Input) panel 1008 connected to each other via a bus 1009, as illustrated in FIG. 1. The CPU 1001 controls the overall numerical control device 40 in accordance with a system program stored in the ROM 1002. In response to a move command for each axis from the CPU 1001, the axis controller 1006 outputs an axis command to a servo amplifier 152, which drives a servo motor 151, provided in a machine tool 50, based on the move command from the axis controller 1006.

Various programs, various data, and various input and output signals are stored in the NAND flash memory 1005 provided in the numerical control device 40 that controls the machine tool 50. An example will be given below.

A machining program for controlling the machine tool 50, for example, is stored in the NAND flash memory 1005. The user, for example, inserts a USB memory, a OF card (Compact Flash® card), or the like storing the machining program into a connector provided in the display device/MDI panel 1008 and loads the machining program into the NAND flash memory 1005. As another example, the user inserts a USB memory or a OF card into a connector provided in the display device/MDI panel 1008 and reads a machining program stored in the NAND flash memory 1005 into the USB memory or the OF card. The machining program is information obtained by programming command processing for allowing the machine tool 50 to perform a prescribed task. The machining program includes, e.g., information such as a command for sending an arbitrary signal to the exterior and a command for reading the state of an arbitrary signal. The machining program further includes, e.g., the information of the task positions and the numbers of signals to be manipulated. Any commands may be used as long as they can be registered on the program, as a matter of course.

The NAND flash memory 1005 stores, e.g., programs associated with an OS (Operating System) and various applications provided by the machine tool manufacturer (MTB (Machine Tool Builder)), and log data associated with, e.g., the operation histories or failure histories for the machine tool 50 and the numerical control device 40. The NAND flash memory 1005 is also used as, e.g., a memory for temporarily storing data associated with the machining details of the machine tool 50 in feeding back these machining details to the machining program. The NAND flash memory 1005 is even used as, e.g., a memory for backup of setting parameters, various data, or the like stored in the ROM 1002 or the RAM 1003 within the numerical control device 40.

A machine learning apparatus according to one embodiment is configured to learn the predicted life of a NAND flash memory provided in an NC (Numerical Control) device for a machine tool. The NC device also includes a CNC (Computerized Numerical. Control) device. Examples of the machine tool include various forms such as a lathe, a drill machine, a boring machine, a milling machine, a grinding machine, a gear cutting machine and gear finishing machine, a machining center, an EDM machine, a punch press machine, a laser machine, a carrier machine, and a plastic injection molding machine, but the machine tool may include forms other than the above-mentioned examples.

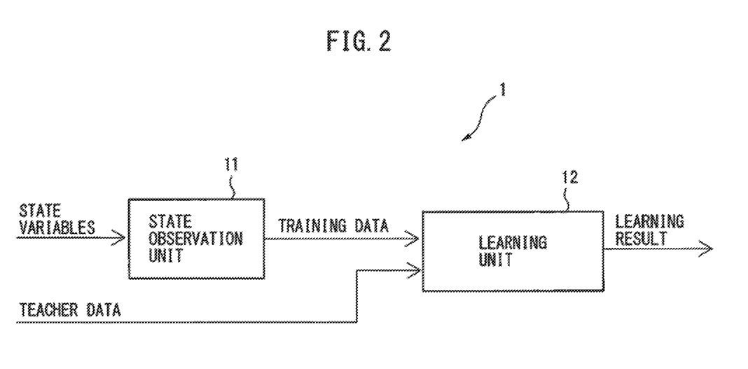

FIG. 2 is a block diagram illustrating a machine learning apparatus according to one embodiment. A machine learning apparatus 1 includes a state observation unit 11 and a learning unit 12. The machine learning apparatus 1 has functions of analytically extracting a useful rule, a knowledge representation, a criterion for judgment, or the like from a set of data inputted to the apparatus, outputting the result of the judgment and performing knowledge learning. In one embodiment of the present disclosure, the machine learning apparatus 1 uses supervised learning and learns the predicted life of a NAND flash memory provided in a numerical control device for a machine tool. In supervised learning, a large number of sets of teacher data, i.e., data of certain inputs and results (labels) are fed to the machine learning apparatus 1 to learn features seen in these data sets and inductively acquire a model (learning model) for estimating the result from the input, i.e., their relationship.

In one embodiment of the present disclosure, the machine learning apparatus 1 observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory, and learns the predicted life of the NAND flash memory using these state variables. The state variables are observed and the predicted life of a NAND flash memory is learned, because the life of the NAND flash memory depends on the rewrite count of the NAND flash memory, the rewrite interval of the NAND flash memory, the read count of the NAND flash memory, the temperature in the use environment of the NAND flash memory, the error rate of the NAND flash memory, information concerning the manufacturer of the NAND flash memory, information concerning the manufacturing lot of the NAND flash memory, information concerning the ECC performance of a memory controller, information concerning the manufacturer of the memory controller, information concerning the manufacturing lot of the memory controller, and the combination of a NAND flash memory and a memory controller which performs ECC processing.

The state observation unit 11 observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory.

Rewrite processing into a NAND flash memory includes information erasure and write. The state observation unit 11 always observes rewrite processing into a NAND flash memory in a numerical control device to acquire data associated with the rewrite count and the rewrite interval. Similarly, the state observation unit 11 always observes read processing into the NAND flash memory in the numerical control device to acquire data associated with the read count. A temperature sensor is placed near the NAND flash memory in the numerical control device, and the state observation unit 11 acquires data associated with the temperature in the use environment of the NAND flash memory from the temperature sensor. In this manner, respective data of the rewrite count, the rewrite interval, the read count, and the temperature in the use environment of the NAND flash memory are acquired from the numerical control device by the state observation unit 11, but respective data of the rewrite count, the rewrite interval, the read count, and the temperature in the use environment of the NAND flash memory may be programmed to be sent to the state observation unit 11 as the operation of the numerical control device.

The error rate of the NAND flash memory is known to gradually rise with an increase in number of rewrite operations. When information concerning the error rate can be obtained from the manufacturer of the NAND flash memory, this information may be inputted to the state observation unit 11. Alternatively, when the error rate of the NAND flash memory can be determined by experiment, the result of this experiment may be inputted to the state observation unit 11. Or again, when the error rate of the NAND flash memory is unknown, an increasing function describing how the error rate increases with time may be defined as appropriate and inputted to the state observation unit 11.

Information concerning the manufacturer and information concerning the manufacturing lot for a NAND flash memory are predefined for the NAND flash memory and are therefore inputted to the state observation unit 11 by, e.g., allowing the user himself or herself to operate an input device.

ECC (Error Correction Coding) processing is performed for a NAND flash memory by a memory controller. The controller that performs ECC processing will be referred to as a “memory controller” in the present disclosure for distinctions from a cell controller (to be described later). Information concerning the ECC performance, information concerning the manufacturer, and information concerning the manufacturing lot for a memory controller which performs ECC processing for a NAND flash memory are predefined for the memory controller that performs the ECC processing and are therefore inputted to the state observation unit 11 by, e.g., allowing the user himself or herself to operate an input device.

The state variables observed by the state observation unit 11 may preferably include at least one of the rewrite count of a NAND flash memory, the rewrite interval of the NAND flash memory, the read count of the NAND flash memory, the temperature in the use environment of the NAND flash memory, the error rate of the NAND flash memory, information concerning the manufacturer of the NAND flash memory, information concerning the manufacturing lot of the NAND flash memory, information concerning the ECC performance of a memory controller, information concerning the manufacturer of the memory controller, and information concerning the manufacturing lot of the memory controller. A state variable (or a combination of state variables) to be observed may be preferably set as appropriate according to the circumstances involved. For example, such state variables may be set in accordance with the operation environment of the numerical control device, set to suit a machine tool controlled by the numerical control device, or set in accordance with the operation period (e.g., the difference in peak time, off-peak time, or the like) of the numerical control device (or the machine tool).

The learning unit 12 learns the predicted life of a NAND flash memory based on teacher data, and training data generated from the output of the state observation unit 11 and data associated with the life of the NAND flash memory. Supervised learning is used as a learning algorithm for the learning unit 12. Teacher data used for supervised learning is data associated with an actual measured life obtained by actually measuring the life of the NAND flash memory. For example, the actual period (by the year, by the month, by the day, or by the hour) from the new condition to the end of the life for a NAND flash memory which has already come to the end of its life (i.e., which has already broken down) is associated with data including at least one of the rewrite count, the rewrite interval, the read count, the temperature in the use environment, the error rate, information concerning the manufacturer, and information concerning the manufacturing lot for the NAND flash memory, and information concerning the ECC (Error Correction Coding) performance, information concerning the manufacturer, and information concerning the manufacturing lot for a memory controller which performs ECC processing for the NAND flash memory. Supervised learning will be described in detail later.

The machine learning apparatus 1 can be provided in, e.g., a numerical control device. The machine learning apparatus 1 may also be, for example, provided on a cloud server via a communication network, provided on a cell controller which controls numerical control devices, or provided on a production management apparatus superior to the cell controller.

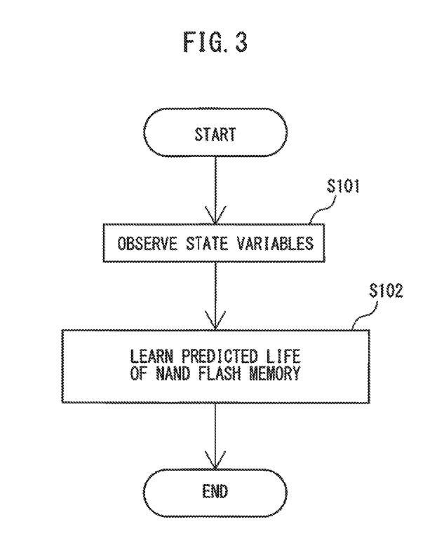

FIG. 3 is a flowchart illustrating the operation sequence of a machine learning method according to one embodiment. A machine learning method for learning the predicted life of a NAND flash memory provided in a numerical control device for a machine tool mainly includes the following two steps.

First, in step S101, the state observation unit 11 observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory.

Then, in step S102, the predicted life of the NAND flash memory is learned based on teacher data, and training data generated from the state variables observed by the state observation unit 11 and data associated with the life of the NAND flash memory. The teacher data means herein data associated with an actual measured life obtained by actually measuring the life of the NAND flash memory.

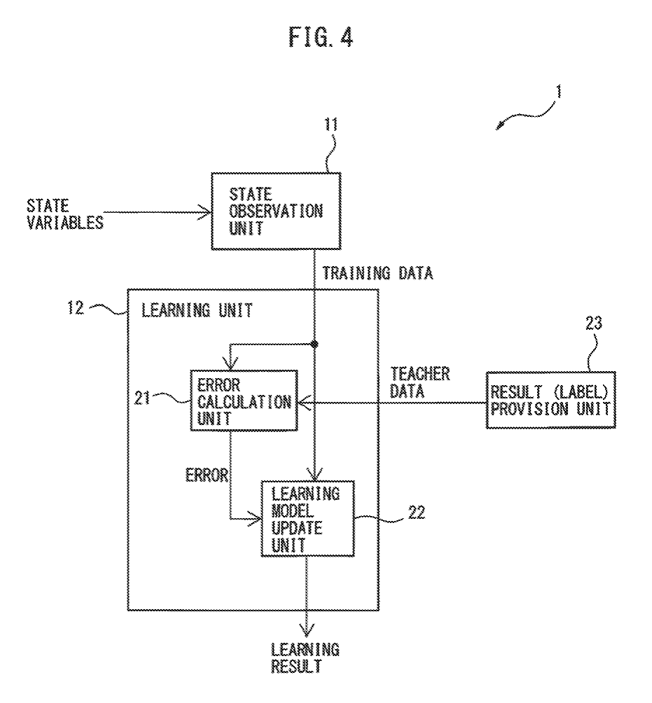

FIG. 4 is a block diagram illustrating the machine learning apparatus using supervised learning according to one embodiment. The learning unit 12 includes an error calculation unit 21 which calculates the error between the training data and the teacher data, and a learning model update unit 22 which updates a learning model for learning the predicted life of the NAND flash memory, based on the output of the state observation unit 11 and the output of the error calculation unit 21. Since components other than the error calculation unit 21 and the learning model update unit 22 are similar to those illustrated in FIG. 1, the same reference numerals denote the same components, and a detailed description thereof will not be given.

The error calculation unit 21 receives teacher data (labeled data) inputted from a result (label) provision unit 23. The result (label) provision unit 23 provides (inputs) teacher data to the error calculation unit 21 of the learning unit 12. The error calculation unit 21 calculates an error using the training data from the state observation unit 11 and the teacher data from the result (label) provision unit 23. The learning model update unit 22 updates a learning model for learning the predicted life of the NAND flash memory, based on the output of the state observation unit 11 and the output of the error calculation unit 21. When, for example, the same processing is performed by the numerical control device, the result (label) provision unit 23 can, for example, retain teacher data obtained by the day before a prescribed day on which the numerical control device is activated, and provide the teacher data retained in the result (label) provision unit 23 to the error calculation unit 21 on the prescribed day.

Alternatively, teacher data obtained through, e.g., simulation performed outside the numerical control device or teacher data for another numerical control device may be provided to the error calculation unit 21 via a memory card or a communication line. The result (label) provision unit 23 may even be built into the learning unit 12 so that teacher data retained in the result (label) provision unit 23 can be directly used in the learning unit 12.

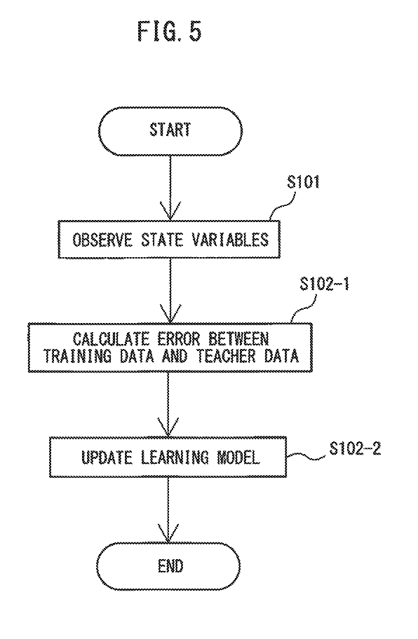

FIG. 5 is a flowchart illustrating the operation sequence of a machine learning method using supervised learning according to one embodiment.

First, in step S101, the state observation unit 11 observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory.

Then, in step S102-1, the error calculation unit 21 calculates the error between teacher data inputted from the result (label) provision unit 23 and training data generated from the state variables observed by the state observation unit 11 and data associated with the life of the NAND flash memory.

In step S102-2, the learning model update unit 22 updates a learning model for learning the predicted life of the NAND flash memory, based on the state variables observed by the state observation unit 11 and the error calculated by the error calculation unit 21.

The machine learning apparatus 1 using supervised learning is implemented using an algorithm such as a neural network, an SVM (Support Vector Machine), a decision tree, or logistic regression. The machine learning apparatus 1 using supervised learning achieves higher-speed processing using, e.g., GPGPUs (General-Purpose computing on Graphics Processing Units) or large-scale PC clusters.

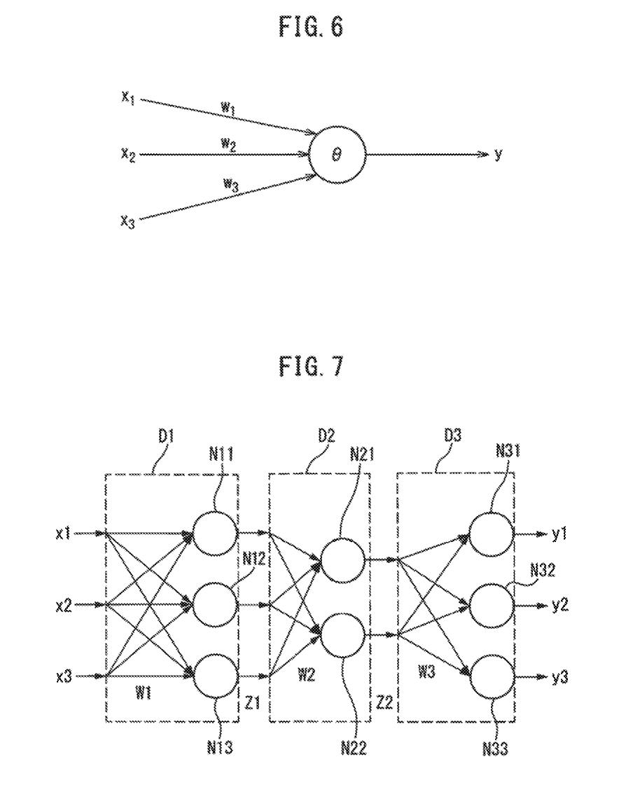

A neural network will be described hereinafter. The neural network includes, e.g., an arithmetic unit and a memory that implement a neural network imitating a model of a neuron as illustrated in, e.g., FIG. 6. FIG. 6 is a schematic diagram illustrating a model of a neuron.

As illustrated in FIG. 6, the neuron outputs an output y for a plurality of inputs x (FIG. 6 illustrates inputs x1 to x3 as an example). Each of the inputs x1 to x3 is multiplied by a weight w (w1 to w3) corresponding to the input x. Thus, the neuron outputs the output y given by:

where θ is the bias and fₖ is the activation function. The input x, the output y, and the weight w are all vectors

y=fₖ(Σᵢ₌₁ⁿx₁w₁−θ) (1)

where θ is the bias and fₖ is the activation function. The input x, the output y, and the weight w are all vectors.

A a neural network having the weights of three layers, which is a combination of neurons as mentioned above, will be described below with reference to FIG. 7. FIG. 7 is a schematic diagram illustrating a neural network having the weights of three layers D1 to D3.

As illustrated in FIG. 7, a plurality of inputs x (by way of example herein, inputs x1 to x3) are inputted from the left hand side of the neural network, and a result y (by way of example herein, results y1 to y3) is outputted from its right hand side.

Specifically, the inputs x1 to x3 are multiplied by a corresponding weight and inputted to each of three neurons N11 to N13. The weights applied to these inputs are collectively indicated by w1.

The neurons N11 to N13 output z11 to z13, respectively. In FIG. 7, z11 to z13 are collectively represented as a feature vector z1, and can be regarded as a vector from which the feature value of the input vector is extracted. The feature vector z1 is a feature vector between the weights w1 and w2. z11 to z13 are multiplied by a corresponding weight and inputted to each of two neurons N21 and N22. The weights applied to these feature vectors are collectively represented as w2.

The neurons N21 and N22 output z21 and z22, respectively. In FIGS. 7, z21 and z22 are collectively represented as a feature vector z2. The feature vector z2 is a feature vector between the weights w2 and w3. The feature vectors z21 and z22 are multiplied by a corresponding weight and inputted to each of three neurons N31 to N33. The weights applied to these feature vectors are collectively represented as w3.

Finally, the neurons N31 to N33 output results y1 to y3, respectively.

The operation of the neural network includes a learning mode and a prediction mode. For example, the weight w is learned using training data and teacher data in the learning mode, and the life of a NAND flash memory provided in a numerical control device is predicted in the prediction mode using the parameters.

It is possible that the numerical control device can be actually operated in the prediction mode to instantly learn and cause the resulting data to be reflected in the subsequent action (on-line learning) and also that a group of pre-collected data can be used to perform collective learning and implement a detection mode with the parameter subsequently for quite a while (batch learning). Alternatively, an intermediate case is also possible, where a learning mode is introduced each time data is accumulated to a certain degree.

The weights w1 to w3 may be learnable by an error back propagation method. The error information enters from the right hand side and flows to the left hand side. The error back propagation method is a technique for adjusting (leaning) each weight so as to minimize the difference between an output y when an input x is inputted and a true output y (teacher) for each neuron.

Such a neural network can have more than three layers (also called deep learning). It is possible to extract features of the input stepwise and automatically acquire an arithmetic unit, which regresses the results, from the teacher data alone.

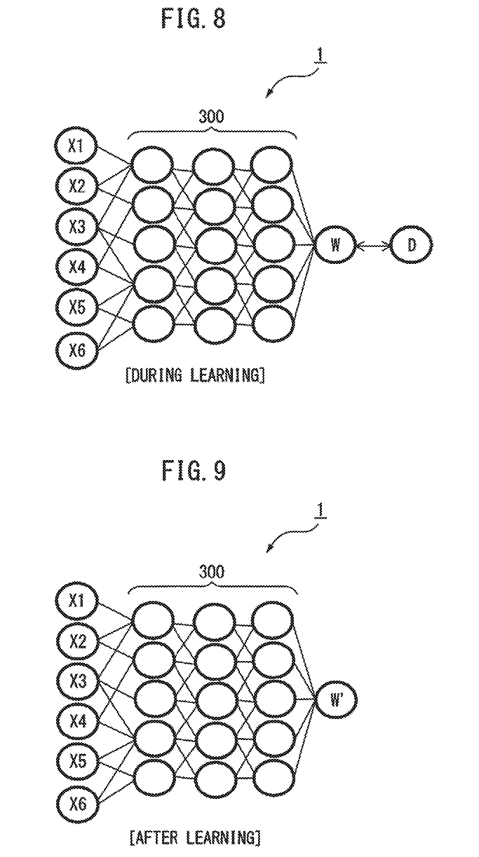

FIG. 8 is a diagram for explaining an exemplary learning mode in the machine learning apparatus using supervised learning according to one embodiment, and FIG. 9 is a diagram for explaining an exemplary prediction mode in the machine learning apparatus using supervised learning according to one embodiment. An example in which the predicted life (its learning model) of a NAND flash memory is learned in the learning mode and the learning result is used in an actual prediction mode to predict the life of the NAND flash memory will be given with reference to FIGS. 8 and 9. Referring to FIGS. 8 and 9, a neural network 300 has three layers for the sake of simplicity, but it may have far more multiple layers.

First, as illustrated in. FIG. 8, in the learning mode, state variables are inputted, including at least one of the rewrite count of a NAND flash memory, the rewrite interval of the NAND flash memory, the read count of the NAND flash memory, the temperature in the use environment of the NAND flash memory, the error rate of the NAND flash memory, information concerning the manufacturer of the NAND flash memory, information concerning the manufacturing lot of the NAND flash memory, information concerning the ECC performance of a memory controller, information concerning the manufacturer of the memory controller, and information concerning the manufacturing lot of the memory controller. The state variables fed to the neural network 300 are not limited to the above-mentioned examples, and they may include other data associated with, e.g., machine tools or workpieces. In an exemplary example illustrated in FIG. 8, six out of these state variables are used as inputs X1 to X6. For example, such state variables are fed to the machine learning apparatus 1 including the neural network 300, with a period of several seconds to several minutes.

As the state variables fed to the neural network 300, not all of X1 to X6 may be fed, and at least one of them may be preferably fed. Further, the state variables fed to the neural network 300 are not limited to X1 to X6, and they may include other data associated with, e.g., machine tools or workpieces (products).

In the learning mode, the machine learning apparatus 1 learns so that training data associated with the predicted life of a NAND flash memory matches teacher data D that is data associated with an actual measured life obtained by actually measuring the life of the NAND flash memory. In other words, upon defining a loss function as y(Xn, W), D, processing is performed in the learning mode until the loss function converges to a certain value.

In the prediction mode, as illustrated in FIG. 5, inputs X1 to X6, for example, are fed to the neural network 300 as inputs; as in the above-mentioned learning mode. The neural network 300 has already been used for learning in the learning mode, and a predicted life W′ of the NAND flash memory corresponding to the inputs X1 to X6 is outputted from the neural network 300.

In the foregoing description, learning of the predicted life of a NAND flash memory in the learning mode is viable even in the prediction mode, as a matter of course. The teacher data fed to the machine learning apparatus 1 may be, e.g., an actual measured life itself, obtained by actually measuring the life of the NAND flash memory, but data of the actual measured life of the NAND flash memory obtained for the inputs X1 to X6 through, e.g., simulation performed outside the numerical control device, or teacher data for another numerical control device, for example, may also be used.

With the above-mentioned machine learning apparatus 1 and machine learning method according to one embodiment, it is possible to accurately grasp the life of a NAND flash memory provided in a numerical control device for a machine tool and appropriately, easily determine whether the end of the life has been reached.

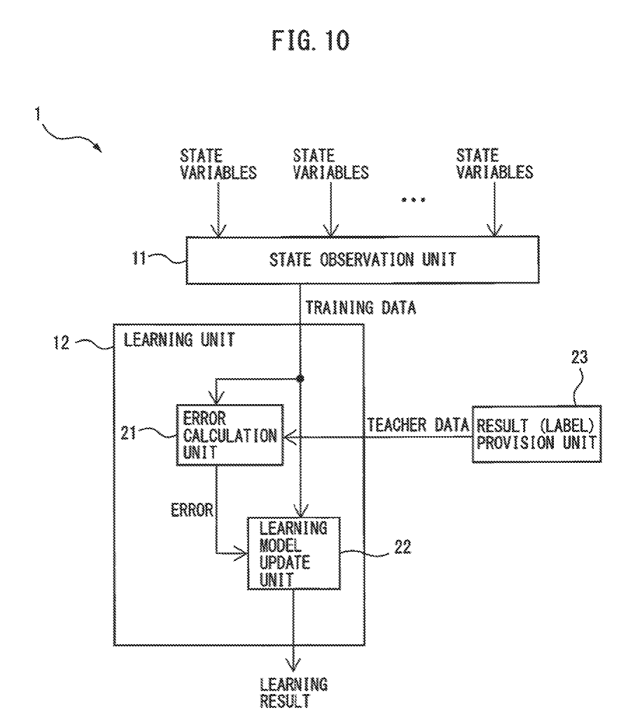

The learning unit 12 in the machine learning apparatus 1 may be configured to learn the predicted life of a NAND flash memory, in accordance with training data acquired for NAND flash memories and/or memory controllers. FIG. 10 is a block diagram illustrating a machine learning apparatus which learns based on training data acquired for NAND flash memories and/or memory controllers. In this embodiment, the state observation unit 11 acquires state variables for the NAND flash memories and/or memory controllers. The “NAND flash memories and/or memory controllers” herein include both NAND flash memories and/or memory controllers in the same numerical control device, and NAND flash memories and/or memory controllers in different numerical control devices. The larger the numbers of NAND flash memories and memory controllers to be observed by the state observation unit 11 in the machine learning apparatus 1, the better the learning effect of the machine learning apparatus 1.

The machine learning apparatus 1 is connectable to at least one different machine learning apparatus and may exchange or share the machine learning results with the at least one different machine learning apparatus. An embodiment of connection of several machine learning apparatuses 1 will be described in detail later.

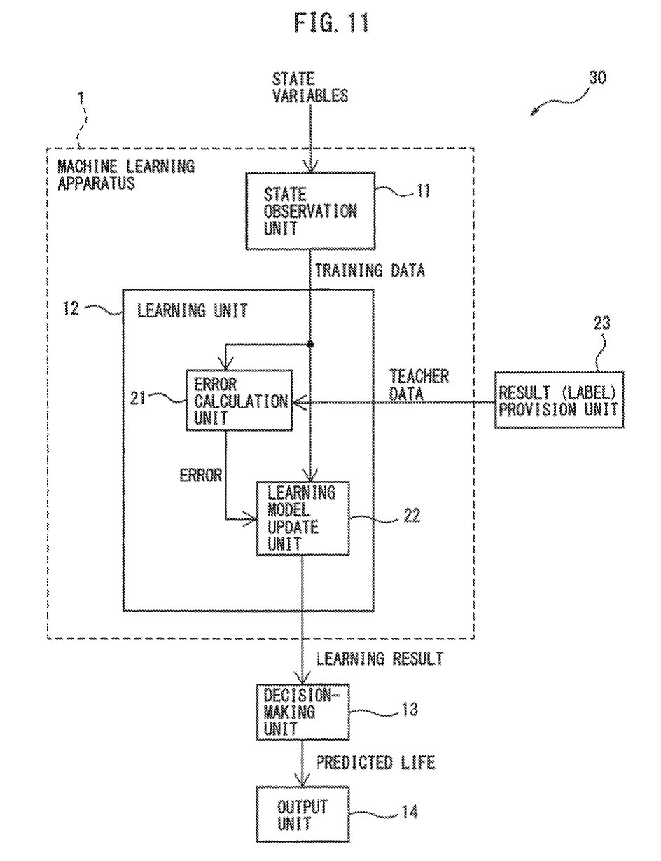

The machine learning apparatus 1 can be used to configure a life prediction apparatus which calculates the predicted life of a NAND flash memory. FIG. 11 is a block diagram illustrating a life prediction apparatus according to one embodiment.

A life prediction apparatus 30 according to one embodiment includes a machine learning apparatus 1, a decision-making unit 13, an output unit 14, and a result (label) provision unit 23.

The state observation unit 11 observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory.

The result (label) provision unit 23 provides (inputs) teacher data to the error calculation unit 21 in the learning unit 12.

The error calculation unit 21 in the learning unit 12 calculates the error between the training data from the state observation unit 11 and the teacher data from the result (label) provision unit 23.

The learning model update unit 22 in the learning unit 12 updates a learning model for learning the predicted life of the NAND flash memory, based on the output of the state observation unit 11 and the output of the error calculation unit 21.

The decision-making unit 13 calculates the predicted life of the NAND flash memory, in response to input of the current state variable, based on the learning result obtained by the learning unit 12.

The output unit 14 outputs data associated with the predicted life of the NAND flash memory calculated by the decision-making unit 13. Based on the data associated with the predicted life of the NAND flash memory outputted from the output unit 14, the user can be notified of this predicted life or notified of a request to replace the NAND flash memory. A notification unit (not illustrated) used for this purpose may be connected to the output unit 14. Examples of the notification unit include a display for a personal computer, a portable terminal, a touch panel, or the like, and a display (the display device/MDI panel 1008 illustrated in FIG. 1) accessory to the numerical control device, and, for example, the predicted life can be displayed on such a display in text or image form. Alternatively, the notification unit may be implemented in, e.g., an acoustic device which emits a sound such as a loudspeaker, a buzzer, or a chime. Or again, the notification unit may take the form of printing out and displaying on, e.g., a sheet surface using a printer. The notification unit may even be implemented by combining the above-mentioned examples together as appropriate. Data associated with the predicted life of the NAND flash memory outputted from the output unit 14 may be stored in a storage device and used for any purpose.

Since the life prediction apparatus 30 allows the user to know the predicted life of a NAND flash memory, the NAND flash memory can be replaced before it becomes inoperable. The inventory of NAND flash memories can even be reduced as the NAND flash memories can be replaced during appropriate periods. Alternatively, as the details of notification by the notification unit, a notification of an operation state that considerably influences the life of the NAND flash memory obtained upon calculation of a predicted life may be sent together. Thus, the user can take a measure to change the operation state that influences the life of the NAND flash memory. The user can take, e.g., a measure to adjust the environment surrounding the numerical control device so as to obtain appropriate temperatures which prolong the life of the NAND flash memory, or a measure to change the operation conditions of the machine tool.

The state observation unit 11, the learning unit 12 including the error calculation unit 21 and the learning model update unit 22, and the decision-making unit 13 may be constructed in the form of, e.g., a software program or constructed in a combination of various electronic circuits and a software program. When, for example, these units are constructed in the form of a software program, the functions of the above-mentioned respective units can be implemented by providing an arithmetic processing unit for operating them in accordance with the software program or operating the software program on a cloud server. Or again, the machine learning apparatus 1 including the state observation unit 11 and the learning unit 12 may be implemented as a semiconductor integrated circuit into which a software program for implementing the function of each unit is written. A semiconductor integrated circuit into which a software program for implementing the function of each unit is written may even be implemented by incorporating not only the machine learning apparatus 1 including the state observation unit 11 and the learning unit 12 but also the decision-making unit 13.

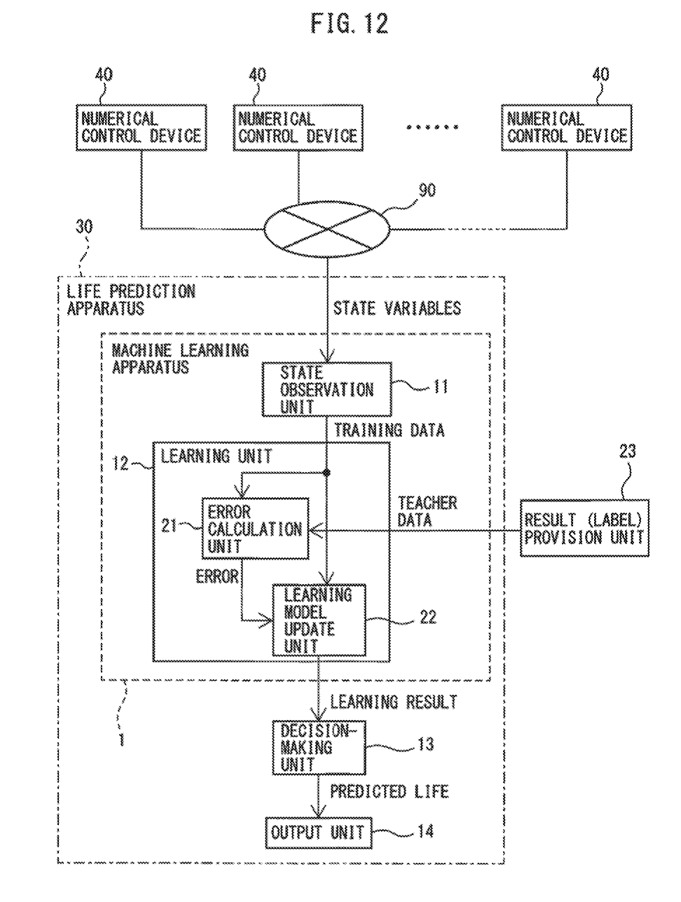

The life prediction apparatus 30 may be connected to the numerical control device via a communication network. FIG. 12 is a block diagram illustrating the life prediction apparatus connected to a communication network according to one embodiment. According to one embodiment, the machine learning apparatus 1 in the life prediction apparatus 30 is communicably connected to numerical control devices 40 via a communication network 90, and the state observation unit 11 observes state variables via the communication network 90. Further, the machine learning apparatus 1 may be provided on a cloud server. In this case, the decision-making unit 13 may be provided on the cloud server to accompany the machine learning apparatus 1, or provided as an independent device other than the cloud server connected via the communication network 90.

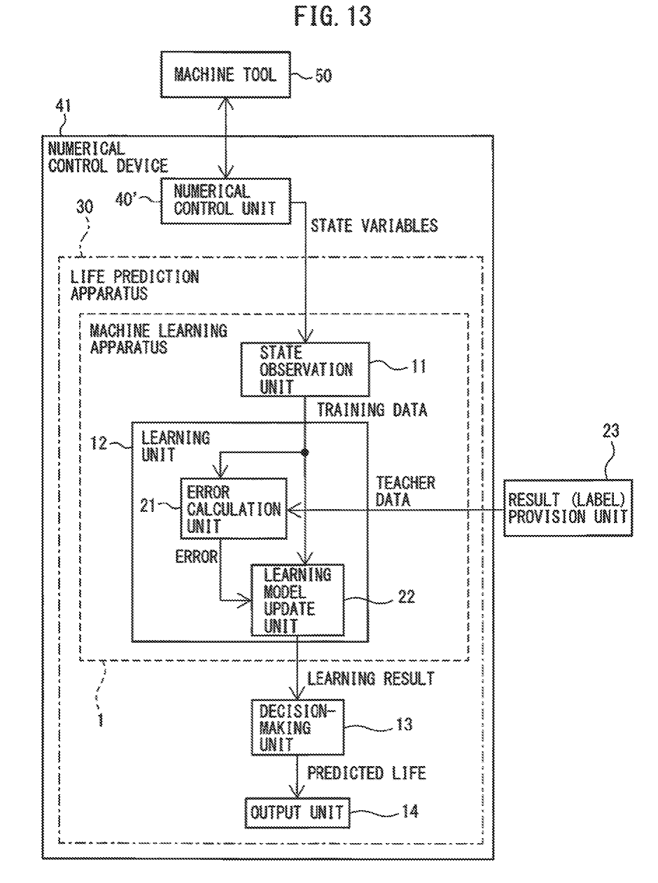

The life prediction apparatus 30 may be provided in a numerical control device. FIG. 13 is a block diagram illustrating a numerical control device including the life prediction apparatus according to one embodiment. According to one embodiment, a numerical control device 41 includes a life prediction apparatus 30. Since the configuration itself of a numerical control unit 40′ which performs numerical control processing for a machine tool 50 by the numerical control device 41 is the same as that of the numerical control device 40 described with reference to FIG. 1, a description thereof will not be given. The state observation unit 11 observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory, within the numerical control unit 40′. Since a learning unit 12, a decision-making unit 13, an output unit 14, and a result (label) provision unit 23 are as described earlier, a description thereof will not be given.

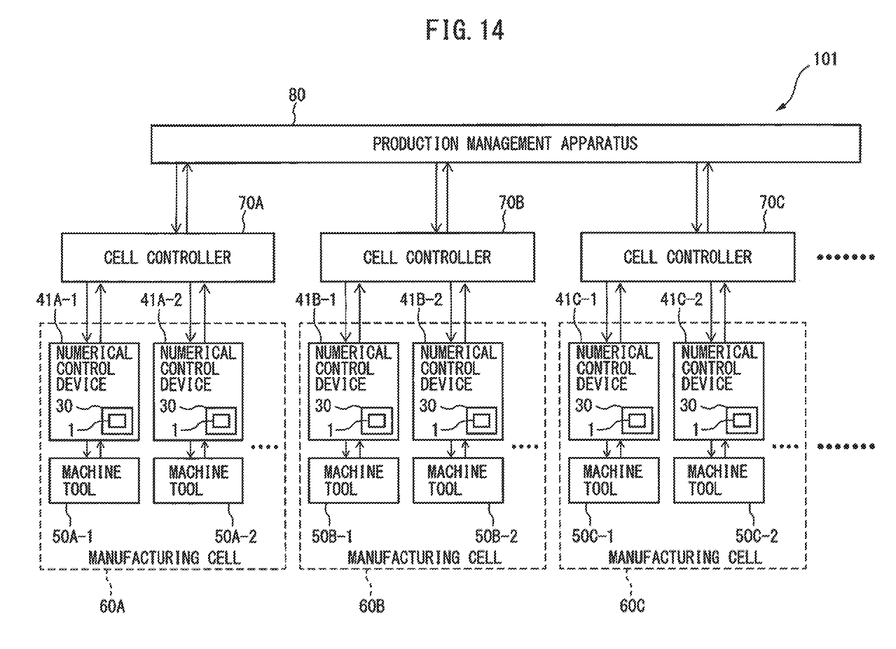

Embodiments in which the life prediction apparatus 30 is provided in a production system including manufacturing cells, cell controllers, and a production management apparatus will be described below with reference to FIGS. 14 to 16. The numbers of manufacturing cells and cell controllers in the production system illustrated in each of FIGS. 14 to 16 to be described hereinafter are merely examples, and different numbers of manufacturing cells and cell controllers may be used.

The manufacturing cell is a set of flexibly combined machine tools which manufacture products. Although the manufacturing cell is formed by, e.g., a plurality of machine tools or a plurality of types of machine tools, the number of machine tools in the manufacturing cell is not particularly limited. For example, the manufacturing cell may serve as a manufacturing line on which a certain workpiece is sequentially processed by the machine tools into a final product. As another example, the manufacturing cell may serve as a manufacturing line on which at least two workpieces (parts) processed by at least two machine tools, respectively, are combined together by another machine tool in the course of the manufacturing process to complete a final workpiece (product). As still another example, at least two workpieces processed by at least two manufacturing cells may be combined together to complete a final workpiece (product). The manufacturing cells and the cell controllers are communicably connected to each other via a communication network such as an intranet. The manufacturing cells are located in a plant which manufactures products. In contrast to this, the cell controllers may be located in a plant equipped with the manufacturing cells, or may be located in a building different from the plant. For example, the cell controllers may be located in a different building located in the site of a plant equipped with the manufacturing cells.

A production management apparatus is provided superior to the cell controllers. The production management apparatus is communicably connected to the cell controllers and issues a production planning instruction to the cell controllers. The production management apparatus may be located in, e.g., an office remote from the plant. In this case, the cell controllers and the production management apparatus are communicably connected to each other via a communication network such as the Internet.

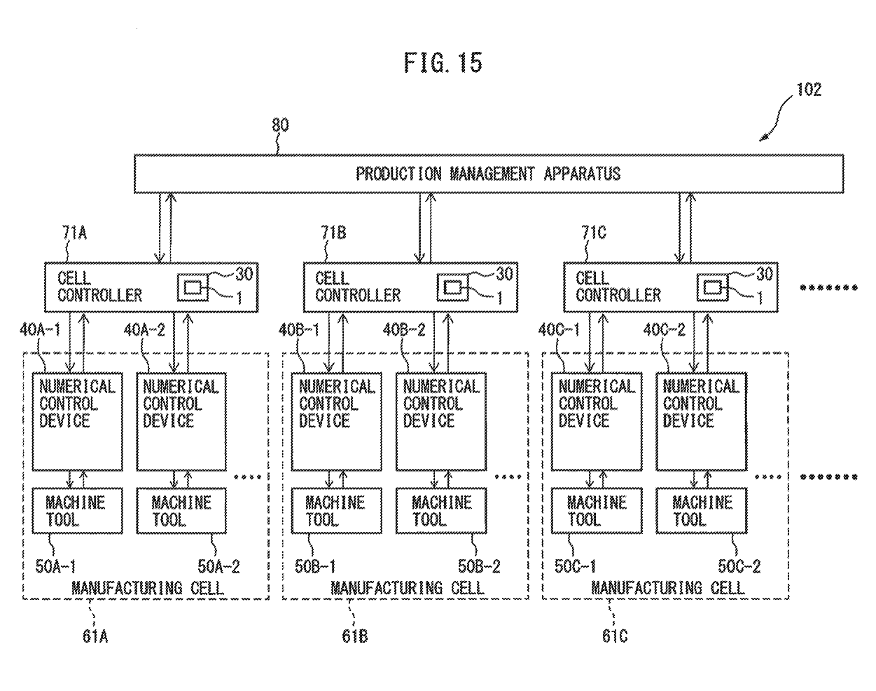

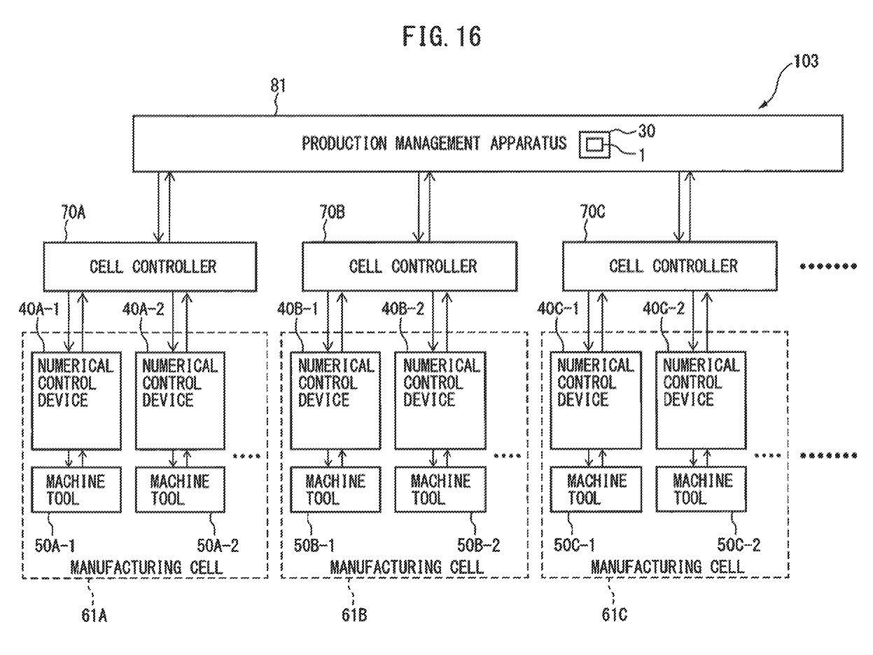

Such a production system will be described below with reference to a first embodiment (FIG. 14) in which the life prediction apparatus 30 is provided in each numerical control device, a second embodiment (FIG. 15) in which the life prediction apparatus 30 is provided in each cell controller, and a third embodiment (FIG. 16) in which the life prediction apparatus 30 is provided in the production management apparatus. These embodiments may be carried out in combination as appropriate.

FIG. 14 is a block diagram illustrating a first embodiment of a production system including the life prediction apparatus. According to the first embodiment, in the production system, the life prediction apparatus 30 illustrated in FIG. 11 is provided in each numerical control device.

A production system 101 according to the first embodiment includes manufacturing cells 60A, 60B, 60C, . . . , cell controllers 70A, 70B, 70C, . . . , and a production management apparatus 80.

The manufacturing cell 60A includes machine tools 50A-1, 50A-2, . . . and numerical control devices 41A-1, 41A-2, . . . provided in correspondence with these machine tools. Similarly, the manufacturing cell 60B includes machine tools 50B-1, 50B-2, . . . and numerical control devices 41B-1, 41B-2, . . . provided in correspondence with these machine tools. The manufacturing cell 60C includes machine tools 50C-1, 50C-2, . . . and numerical control devices 41C-1, 41C-2, . . . provided in correspondence with these machine tools.

Each of the numerical control devices 41A-1, 41A-2, . . . , 41B-1, 41B-2, . . . , and 41C-1, 41C-2, . . . includes the life prediction apparatus 30 described with reference to FIG. 11. In other words, the numerical control devices 41A-1, 41A-2, . . . , 41B-1, 41B-2, . . . , and 41C-1, 41C-2, . . . are individually identical to the numerical control device 41 including the life prediction apparatus 30 described with reference to FIG. 13. A state observation unit 11 (not illustrated in FIG. 14) in a machine learning apparatus 1 provided in each of the numerical control devices 41A-1, 41A-2, . . . , 41B-1, 41B-2, . . . , and 41C-1, 41C-2, . . . observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory, within the numerical control device. An output unit 14 (not illustrated in FIG. 14) in the machine learning apparatus 1 provided in each of the numerical control devices 41A-1, 41A-2, . . . , 41B-1, 41B-2, . . . , and 41C-1, 41C-2, . . . outputs data associated with the predicted life of the NAND flash memory provided in each of these numerical control devices calculated by a decision-making unit 13 (not illustrated in FIG. 14) to the corresponding cell. controllers 70A, 70B, 70C, . . . provided to control these numerical control devices.

The manufacturing cells 60A, 60B, and 60C are communicably connected to the cell controllers 70A, 70B, and 70C, respectively, via a communication network. The cell controller 70A controls the numerical control devices 41A-1, 41A-2, . . . in the manufacturing cell 60A. The cell controller 70B controls the numerical control devices 41B-1, 41B-2, . . . in the manufacturing cell 60B. The cell controller 70C controls the numerical control devices 41C-1, 41C-2, . . . in the manufacturing cell 60C.

The production management apparatus 80 is communicably connected to the cell controllers 70A, 70B, 70C, . . . via a communication network and issues a production planning instruction to the cell controllers 70A, 70B, 70C, . . . .

In the production system 101 according to the first embodiment, the cell controllers 70A, 70B, 70C, . . . or the production management apparatus 80 superior to the cell controllers 70A, 70B, 70C, . . . displays the predicted life of the NAND flash memory on a display device provided in each of the cell controllers 70A, 70B, 70C, . . . or the production management apparatus, based on data associated with the predicted life outputted from the output unit 14 of each machine learning apparatus 1. Alternatively, instead of or in addition to a display device, an alarm sound or a buzzer may be emitted by an acoustic device to notify the user of the predicted life of the NAND flash memory. Thus, the user working in the plant can easily know the predicted life of the NAND flash memory and, in turn, can know that the period to replace the NAND flash memory has come. The production management apparatus 80 may use the predicted life of the NAND flash memory in formulating a production plan.

With the production system 101 according to the first embodiment, the machine learning apparatus 1 provided in each of the numerical control devices 41A-1, 41A-2, . . . , 41B-1, 41B-2, . . . , and 41C-1, 41C-2, . . . performs distributed learning of the predicted life of a NAND flash memory provided in this numerical control apparatus. In the same manufacturing cell, the machine learning apparatus 1 is communicably connected to different machine learning apparatuses via a cell controller for this manufacturing cell and may therefore exchange or share the machine learning results with the different machine learning apparatuses. Alternatively, the machine learning apparatus 1 is communicably connected to different machine learning apparatuses via the production management apparatus 80 superior to the cell controllers 70A, 70B, 70C, . . . and may therefore exchange or share the machine learning results with the different machine learning apparatuses. The learning effect can further be improved by exchanging or sharing the machine learning results among the machine learning apparatuses.

FIG. 15 is a block diagram illustrating a second embodiment of a production system including the life prediction apparatus. According to the second embodiment, in the production system, the life prediction apparatus 30 illustrated in FIG. 11 is provided in each cell controller.

A production system 102 according to the second embodiment includes manufacturing cells 61A, 61B, 61C, . . . , cell controllers 71A, 71B, 71C, . . . , and a production management apparatus 80.

The manufacturing cell 61A includes machine tools 50A-1, 50A-2, . . . and numerical control devices 40A-1, 40A-2, . . . provided in correspondence with these machine tools. Similarly, the manufacturing cell. 61B includes machine tools 50B-1, 50B-2, . . . and numerical control devices 40B-1, 40B-2, . . . provided in correspondence with these machine tools. The manufacturing cell 61C includes machine tools 50C-1, 50C-2, . . . and numerical control devices 40C-1, 40C-2, . . . provided in correspondence with these machine tools. The configurations of the numerical control devices 40A-1, 40A-2, . . . , 40B-1, 40B-2, . . . , and 40C-1, 40C-2, . . . are the same as that of the numerical control device 40 described with reference to FIG. 1.

The manufacturing cells 61A, 61B, and 61C are communicably connected to the cell controllers 71A, 71B, and 71C, respectively, via a communication network. The cell controller 71A controls the numerical control devices 40A-1, 40A-2, . . . in the manufacturing cell 61A. The cell controller 71B controls the numerical control devices 40B-1, 40B-2, . . . in the manufacturing cell 61B. The cell controller 71C controls the numerical control devices 40C-1, 40C-2, . . . in the manufacturing cell 61C. Each of the cell controllers 71A, 71B, 71C, . . . includes the life prediction apparatus 30 described with reference to FIG. 11. A state observation unit 11 (not illustrated in FIG. 15) in a machine learning apparatus 1 provided in each of the cell controllers 71A, 71B, 71C, . . . observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory, within the numerical control device controlled by each of these cell controllers. An output unit 14 (not illustrated in FIG. 15) in the machine learning apparatus 1 provided in each of the cell controllers 71A, 71B, 71C, outputs data associated with the predicted life of the NAND flash memory provided in the numerical control device controlled by each of these cell controllers, calculated by a decision-making unit 13 (not illustrated in FIG. 15), to the production management apparatus 80.

The production management apparatus 80 is communicably connected to the cell controllers 71A, 71B, 71C, . . . via a communication network and issues a production planning instruction to the cell controllers 71A, 71B, 71C, . . . .

In the production system 102 according to the second embodiment, the cell controllers 71A, 71B, 71C, . . . or the production management apparatus 80 superior to the cell controllers 71A, 71B, 71C, . . . displays the predicted life of the NAND flash memory on a display device provided in each of the cell controllers 71A, 71B, 71C, . . . or the production management apparatus, based on data associated with the predicted life outputted from the output unit 14 of each machine learning apparatus 1. Alternatively, instead of or in addition to a display device, an alarm sound or a buzzer may be emitted by an acoustic device to notify the user of the predicted life of the NAND flash memory. Thus, the user working in the plant can easily know the predicted life of the NAND flash memory and, in turn, can know that the period to replace the NAND flash memory has come. The production management apparatus 80 may use the predicted life of the NAND flash memory in formulating a production plan.

With the production system 102 according to the second embodiment, the machine learning apparatus 1 provided in each of the cell controllers 71A, 71B, 71C, . . . performs distributed learning of the predicted life of the NAND flash memory provided in the numerical control device controlled by each of these cell controllers. The machine learning apparatus 1 is communicably connected to different machine learning apparatuses via the production management apparatus 80 superior to the cell controllers 71A, 71B, 71C, . . . and may therefore exchange or share the machine learning results with the different machine learning apparatuses. The learning effect can further be improved by exchanging or sharing the machine learning results among the machine learning apparatuses.

FIG. 16 is a block diagram illustrating a third embodiment of a production system including the life prediction apparatus. According to the third embodiment, in the production system, the life prediction apparatus 30 illustrated in FIG. 11 is provided in each numerical control device.

A production system 103 according to the third embodiment includes manufacturing cells 61A, 61B, 61C, . . . , cell controllers 70A, 70B, 70C, . . . , and a production management apparatus 81.

The manufacturing cell 61A includes machine tools 50A-1, 50A-2, . . . and numerical control devices 40A-1, 40A-2, . . . provided in correspondence with these machine tools. Similarly, the manufacturing cell 61B includes machine tools 50B-1, 50B-2, . . . and numerical control devices 40B-1, 40B-2, . . . provided in correspondence with these machine tools. The manufacturing cell 61C includes machine tools 50C-1, 50C-2, . . . and numerical control devices 40C-1, 40C-2, . . . provided in correspondence with these machine tools. The configurations of the numerical control devices 40A-1, 40A-2, . . . , 40B-1, 40B-2, . . . , and 40C-1, 40C-2, . . . are the same as that of the numerical control device 40 described with reference to FIG. 1.

The manufacturing cells 61A, 61B, and 61C are communicably connected to the cell controllers 70A, 70B, and 70C, respectively, via a communication network. The cell controller 70A controls the numerical control devices 40A-1, 40A-2, in the manufacturing cell 61A. The cell controller 70B controls the numerical control devices 40B-1, 40B-2, . . . in the manufacturing cell 61B. The cell controller 70C controls the numerical control devices 40C-1, 40C-2, . . . in the manufacturing cell 61C.

The production management apparatus 81 is communicably connected to the cell controllers 70A, 70B, 70C, . . . via a communication network and issues a production planning instruction to the cell controllers 70A, 70B, 70C, . . . . The production management apparatus 81 includes the life prediction apparatus 30 described with reference to FIG. 11. A state observation unit 11 (not illustrated in FIG. 16) in a machine learning apparatus 1 provided in the production management apparatus 81 observes state variables obtained based on at least one of the rewrite count, the rewrite interval, the read count, the temperature in the use environment, the error rate, information concerning the manufacturer, and information concerning the manufacturing lot for a NAND flash memory, and information concerning the ECC (Error Correction Coding) performance, information concerning the manufacturer, and information concerning the manufacturing lot for a memory controller which performs ECC processing for the NAND flash memory, within each numerical control device. An output unit 14 (not illustrated in FIG. 16) in the machine learning apparatus 1 provided in the production management apparatus 81 outputs data associated with the predicted life of the NAND flash memory provided in the numerical control device controlled by each of the cell controllers 70A, 70B, 70C, . . . , calculated by a decision-making unit 13 (not illustrated in FIG. 16).

In the production system 103 according to the third embodiment, the production management apparatus 81 displays the predicted life of the NAND flash memory on a display device provided in the production management apparatus 81, based on data associated with the predicted life outputted from the output unit 14 of the machine learning apparatus 1. Alternatively, instead of or in addition to a display device, an alarm sound or a buzzer may be emitted by an acoustic device to notify the user of the predicted life of the NAND flash memory. Thus, the user working in the plant can easily know the predicted life of the NAND flash memory and, in turn, can know that the period to replace the NAND flash memory has come. The production management apparatus 81 may use the predicted life of the NAND flash memory in formulating a production plan. Alternatively, data associated with the predicted life outputted from the output unit 14 of the machine learning apparatus 1 in the production management apparatus 81 may be transferred to the cell controllers 71A, 71B, 71C, . . . , and the predicted life of the NAND flash memory may be displayed on a display device provided in each of the cell controllers 71A, 71B, 71C, . . . , or instead of or in addition to a display device, an alarm sound or a buzzer may be emitted by an acoustic device to notify the user of the predicted life of the NAND flash memory.

With the production system 103 according to the third embodiment, the machine learning apparatus 1 provided in the production management apparatus 81 learns the predicted life of a NAND flash memory provided in a numerical control device. Since the machine learning apparatus 1 learns the predicted lives of NAND flash memories provided in a large number of numerical control devices, the learning effect improves.

The above-described production system is implemented in a three-layer network system including manufacturing cells, cell controllers, and a production management system. As a modification to this embodiment, the production management system may be omitted to implement a production system in a two-layer network system including manufacturing cells and cell controllers, and in this case, the life prediction apparatus 30 may be preferably provided in a cell controller or a numerical control device within a manufacturing cell. Alternatively, a production system may be implemented in a network system having four or more layers, and in this case, the life prediction apparatus 30 may be preferably provided in a numerical control device within a manufacturing cell, a cell controller, a production management apparatus, or an apparatus superior to them. Or again, a production system may be connected to a communication network located outside it, and in this case, the life prediction apparatus 30 may be provided on a cloud server via the communication network.

As described above, with a machine learning apparatus which learns the predicted life of a NAND flash memory provided in a numerical control device for a machine tool according to one embodiment, it is possible to accurately grasp the life of the NAND flash memory provided in the numerical control device for the machine tool and appropriately, easily determine whether the end of the life has been reached. The machine learning apparatus using supervised learning is implemented using an algorithm such as a neural network, an SVM (Support Vector Machine), a decision tree, or logistic regression.

A life prediction apparatus according to one embodiment includes a machine learning apparatus, a decision-making unit which calculates the predicted life of a NAND flash memory, and an output unit which outputs the predicted life of the NAND flash memory calculated by the decision-making unit. Since the life prediction apparatus allows the user to know the predicted life of a NAND flash memory, the NAND flash memory can be replaced before it becomes inoperable. The inventory of NAND flash memories can even be reduced as the NAND flash memories can be replaced during appropriate periods. Alternatively, as the details of notification by the notification unit, a notification of an operation state that considerably influences the life of the NAND flash memory obtained upon calculation of a predicted life may be sent together, and this allows the user to take a measure to change the operation state that influences the life of the NAND flash memory. The user can take, e.g., a measure to adjust the environment surrounding the numerical control device so as to obtain appropriate temperatures which prolong the life of the NAND flash memory, or a measure to change the operation conditions of the machine tool.

The machine learning apparatus is connectable to at least one different machine learning apparatus and may exchange or share the machine learning results with the at least one different machine learning apparatus. Thus, the learning effect can further be improved by exchanging or sharing the machine learning results among the machine learning apparatuses.

The learning unit in the machine learning apparatus may be configured to learn the predicted life of a NAND flash memory, in accordance with training data acquired for NAND flash memories and/or memory controllers. The larger the numbers of NAND flash memories and memory controllers to be observed by the state observation unit 11 in the machine learning apparatus 1, the better the learning effect of the machine learning apparatus 1.

The machine learning apparatus may be communicably connected to the numerical control device via a communication network or may be located on a cloud server. Such a network connection architecture between the machine learning apparatus and the numerical control device can easily cope with changes in number of numerical control devices, and can even easily exchange or share the machine learning results among the machine learning apparatuses.

The life prediction apparatus may be provided in a numerical control device, in a cell controller which controls the numerical control device, or in a production management apparatus which issues a production planning instruction to the cell controller. Thus, the user working in a plant equipped with a machine tool connected to the numerical control device can easily know the predicted life of a NAND flash memory provided in the numerical control device and, in turn, can know that the period to replace the NAND flash memory has come. The production management apparatus may use the predicted life of the NAND flash memory in formulating a production plan, and this improves the economy.

According to one aspect, it is possible to accurately grasp the life of a NAND flash memory provided in a numerical control device for a machine tool and appropriately, easily determine whether the end of the life has been reached.

1. A machine learning apparatus which learns a predicted life of a NAND flash memory provided in a numerical control device for a machine tool, the apparatus comprising:
a state observation unit which observes a state variable obtained based on at least one of a rewrite count, a rewrite interval, a read count, a temperature in a use environment, an error rate, information concerning a manufacturer, and information concerning a manufacturing lot for the NAND flash memory, and information concerning an error correction coding performance, information concerning a manufacturer, and information concerning a manufacturing lot for a memory controller which performs error correction coding processing for the NAND flash memory; and
a learning unit which learns the predicted life of the NAND flash memory based on teacher data, and training data generated from output of the state observation unit and data associated with a life of the NAND flash memory.

2. The machine learning apparatus according to claim 1, wherein the learning unit comprises:
an error calculation unit which calculates an error between the training data and the teacher data; and
a learning model update unit which updates a learning model for learning the predicted life of the NAND flash memory, based on the output of the state observation unit and output of the error calculation unit.

3. The machine learning apparatus according to claim 1, wherein the teacher data comprises data associated with an actual measured life obtained by actually measuring the life of the NAND flash memory.

4. The machine learning apparatus according to claim 1, wherein the machine learning apparatus is connectable to at least one different machine learning apparatus and exchanges or shares a machine learning result with the at least one different machine learning apparatus.

5. The machine learning apparatus according to claim 1, wherein the learning unit is configured to learn the predicted life of the NAND flash memory in accordance with the training data acquired for NAND flash memories and/or memory controllers.

6. A life prediction apparatus comprising:
the machine learning apparatus according to claim 1;
a decision-making unit which calculates the predicted life of the NAND flash memory, in response to input of a current state variable of the state variable, based on a learning result obtained by the learning unit; and
an output unit which outputs the predicted life of the NAND flash memory calculated by the decision® making unit.

7. The life prediction apparatus according to claim 6, wherein
the machine learning apparatus is communicably connected to the numerical control device via a communication network, and
the state observation unit observes the state variable via the communication network.

8. A numerical control device comprising the life prediction apparatus according to claim 6.

9. A production system comprising:
a manufacturing cell comprising combinations of machine tools and numerical control devices according to claim 8 provided in correspondence with the machine tools; and
a cell controller which is communicably connected to the manufacturing cell via a communication network and controls the numerical control devices.

10. A production system comprising:
a manufacturing cell comprising combinations of machine tools and numerical control devices provided in correspondence with the machine tools; and
a cell controller which is communicably connected to the manufacturing cell via a communication network and controls the numerical control devices,
wherein the cell controller comprises the life prediction apparatus according to claim 6.

11. The production system according to claim 9, further comprising a production management apparatus which is communicably connected to the cell controller via a communication network and issues a production planning instruction to the cell controller.

12. A production system comprising:
a manufacturing cell comprising combinations of machine tools and numerical control devices provided in correspondence with the machine tools;
a cell controller which is communicably connected to the manufacturing cell via a communication network and controls the numerical control devices; and
a production management apparatus which is communicably connected to the cell controller via a communication network and issues a production planning instruction to the cell controller,
wherein the production management apparatus comprises the life prediction apparatus according to claim 6.

13. A machine learning method for learning a predicted life of a NAND flash memory provided in a numerical control device for a machine tool, the method comprising the steps of:
observing a state variable obtained based on at least one of a rewrite count, a rewrite interval, a read count, a temperature in a use environment, an error rate, information concerning a manufacturer, and information concerning a manufacturing lot for the NAND flash memory, and information concerning an error correction coding performance, information concerning a manufacturer, and information concerning a manufacturing lot for a memory controller which performs error correction coding processing for the NAND flash memory; and
learning the predicted life of the NAND flash memory based on teacher data, and training data generated from the state variable and data associated with a life of the NAND flash memory.

14. The machine learning method according to claim 13, wherein the step of learning the predicted life of the NAND flash memory comprises the steps of:
calculating an error between the training data and the teacher data; and
updating a learning model for learning the predicted life of the NAND flash memory, based on the state variable and the calculated error between the training data and the teacher data.

15. The machine learning method according to claim 13, wherein the teacher data comprises data associated with an actual measured life obtained by actually measuring the life of the NAND flash memory.
